(19) United States
(12) Patent Application Publication
(10) Pub. No.: US 2024/0328032 A1
(43) Pub. Date: Oct. 3, 2024

(54) SUPPORT PLATE, SUPPORT TOOL, AND METHOD FOR MANUFACTURING SEMICONDUCTOR SUBSTRATE

(71) Applicant: ROHM CO., LTD., Kyoto-shi (JP)

(72) Inventors: Makoto TAKAMURA, Kyoto-shi (JP); Mitsuru MORIMOTO, Kyoto-shi (JP); Takuji MAEKAWA, Kyoto-shi (JP)

(73) Assignee: ROHM CO., LTD., Kyoto-shi (JP)

(21) Appl. No.: 18/613,188

(22) Filed: Mar. 22, 2024

(30) Foreign Application Priority Data
Mar. 31, 2023 (JP) 2023-058163

(51) Int. Cl. C30B 28/14; C30B 29/36; C30B 31/22; C30B 33/02

(52) U.S. Cl. CPC C30B 28/14; C30B 29/36; C30B 31/22; C30B 33/02

(57) ABSTRACT

The present disclosure provides a support tool, for a temporary substrate using a support plate. The support tool includes: a first dummy substrate and a second dummy substrate; and a support, supporting the first dummy substrate and the second dummy substrate, and including at least three of the support plates. The support plate is fitted with the first dummy substrate through a first groove of the plurality of grooves, and fitted with the second dummy substrate through a second groove of the plurality of grooves. The support is configured to support the temporary substrate inserted into a third groove of the plurality of grooves of the support plate excluding the first groove and the second groove.

### TECHNICAL FIELD

The present disclosure relates to a support plate, a support tool, and a method for manufacturing a semiconductor substrate.

### BACKGROUND

In the past, SiC power devices, such as Schottky barrier diode (SBD), metal-oxide-semiconductor field effect transistor (MOSFET) and insulated gate bipolar transistor (IGBT), have been provided for power control purposes. In order to reduce manufacturing costs or provide required physical properties, the SiC semiconductor substrate forming such a SiC device may be produced by bonding a single crystal SiC semiconductor substrate to a polycrystalline SiC semiconductor substrate. Patent Document 1 describes the following technique: a single crystal SiC semiconductor substrate is attached to a polycrystalline SiC semiconductor substrate without defects so that the epitaxial layer is grown on the single crystal SiC semiconductor substrate attached to the polycrystalline SiC semiconductor substrate.

### PRIOR ART DOCUMENTS

### Patent Documents

[Patent Document 1] Specification of U.S. Pat. No. 8,916,451.

### BRIEF DESCRIPTION OF THE DRAWINGS

FIG. 1 shows a perspective view of a support tool.

FIG. 2 shows a front view of the support tool.

FIG. 3 shows a top view of the support tool.

FIG. 4 shows a perspective view of the support tool accommodating temporary substrates.

FIG. 5 shows a front view of the support tool accommodating temporary substrates.

FIG. 6 shows a front view, a side view and a bottom view of a support plate.

FIG. 7A shows a top view of a dummy substrate.

FIG. 7B shows a side view of the dummy substrate.

FIG. 8 shows a front view, a side view and a bottom view of a support plate according to a modified example.

FIG. 9 shows a cross-sectional view of a SiC single crystal substrate.

FIG. 10A is a top view illustrating a crystal plane of a SiC wafer.

FIG. 10B is a side view illustrating the crystal plane of the SiC wafer.

FIG. 11A shows a perspective view of an unit cell of a 4H-SiC crystal.

FIG. 11B shows a structural diagram of a two-layer portion of the 4H-SiC crystal.

FIG. 11C shows a structural diagram of a four-layer portion of the 4H-SiC crystal.

FIG. 12 shows a structural diagram of the unit cell of the 4H-SiC crystal shown in FIG. 11A viewed from directly above the (0001) plane.

FIG. 13 shows a cross-sectional view of a structure in which a first graphene layer is formed on a SiC single crystal substrate.

FIG. 14 shows a cross-sectional view of a structure in which a SiC epitaxial growth layer is formed on the first graphene layer.

FIG. 15 shows a cross-sectional view of a structure in which a stress layer is formed on the SiC epitaxial growth layer.

FIG. 16 shows a cross-sectional view of a structure in which the stress layer is bonded to a graphite substrate via an adhesive layer.

FIG. 17A shows a cross-sectional view of the SiC epitaxial growth layer side of a structure resulted after the stress layer has been bonded to the graphite substrate via the adhesive layer and peeling has occurred at the interface between the SiC epitaxial growth layer and the graphene layer.

FIG. 17B shows a cross-sectional view of the graphene layer side of the structure resulted after the stress layer has been bonded to the graphite substrate via the adhesive layer and peeling has occurred at the interface between the SiC epitaxial growth layer and the graphene layer.

FIG. 18 shows a cross-sectional view of a structure resulted after the peeled structure of FIG. 17A has been attached to both sides of the graphite substrate and the adhesive layer has been carbonized by annealing treatment.

FIG. 19 shows a cross-sectional view of the structure of FIG. 18 supported in the support tool.

FIG. 20 shows a cross-sectional view of a structure in which a SiC polycrystalline growth layer is formed by a CVD method.

FIG. 21 shows a top view of the structure in which the SiC polycrystalline growth layer is formed by the CVD method.

FIG. 22 shows a cross-sectional view of a structure cut out from the support tool after cutting the structure of FIG. 21.

FIG. 23 shows a cross-sectional view of the structure of FIG. 18 supported in the support tool of a modified example.

FIG. 24 shows a cross-sectional view of the structure of FIG. 18 cut out from the support tool of the modified example after the SiC polycrystalline growth layer has been formed by a CVD method.

FIG. 25 shows a cross-sectional view of a structure resulted after the graphite substrate and the carbonized adhesive layer have been removed by combustion.

FIG. 26 shows a cross-sectional view of a structure of the SiC composite substrate made by removing the periphery SiC polycrystalline growth layer and the stress layer.

FIG. 27 shows a cross-sectional view of the SiC composite substrate.

FIG. 28 shows a perspective view of the SiC composite substrate (wafer).

FIG. 29 shows a cross-sectional view of a structure in which a hydrogen ion implantation layer is formed on the Si surface of the SiC single crystal substrate.

FIG. 30 shows a cross-sectional view of a structure resulted after the hydrogen ion implanted layer has been embrittled by annealing the hydrogen ion implanted layer to form a thinned single crystal SiC layer and a SiC epitaxial growth layer has been formed on the Si surface of the thinned single crystal SiC layer.

FIG. 31 shows a cross-sectional view of a structure in which the Si surface of the SiC epitaxial growth layer is attached to a graphite substrate through an adhesive layer.

FIG. 32 shows a cross-sectional view of a structure resulted after the SiC single crystal substrate has been peeled off and separated through the thinned single crystal SiC layer formed by embrittlement annealing.

FIG. 33 shows a cross-sectional view of a structure in which the peeling surface of the thinned single crystal SiC layer has been smoothed.

FIG. 34 shows a cross-sectional view of the structure of FIG. 33 supported in the support tool.

FIG. 35 shows a cross-sectional view of a structure in which a SiC polycrystalline growth layer is formed by the CVD method.

FIG. 36 shows a cross-sectional view of a structure cut out from the support tool after cutting the structure of FIG. 35.

FIG. 37 is a cross-sectional view showing the graphite substrate has been removed from the structure of FIG. 36 by combustion.

FIG. 38 shows a cross-sectional view of the SiC composite substrate obtained by removing the peripheral SiC polycrystalline growth layer and the stress layer from the upper structure of FIG. 37.

### DETAILED DESCRIPTION OF THE EMBODIMENTS

Next, embodiments will be illustrated with reference to the accompanying drawings. In the illustration of the drawings described below, the same or similar parts are denoted by the same or similar symbols. The drawings are schematic diagrams. In addition, the embodiments illustrated below exemplifies devices or methods for embodying technical ideas, and do not specify the materials, shapes, structures, arrangements, etc. of components. Various modifications can be made to the embodiments.

### Support Plate and Support Tool

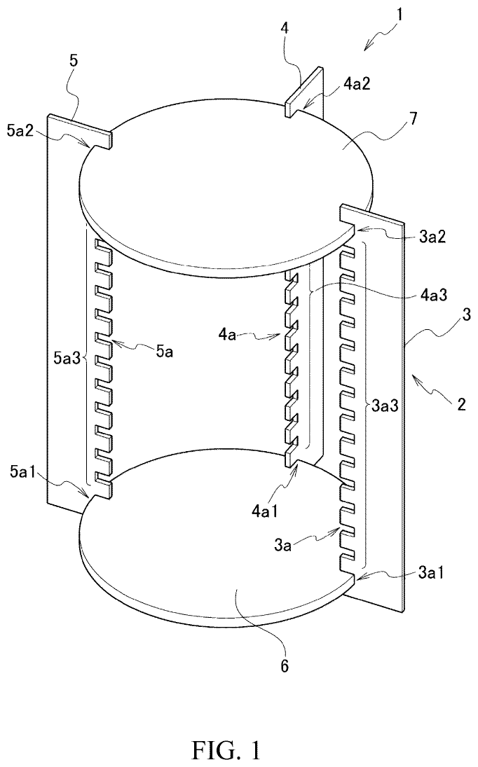

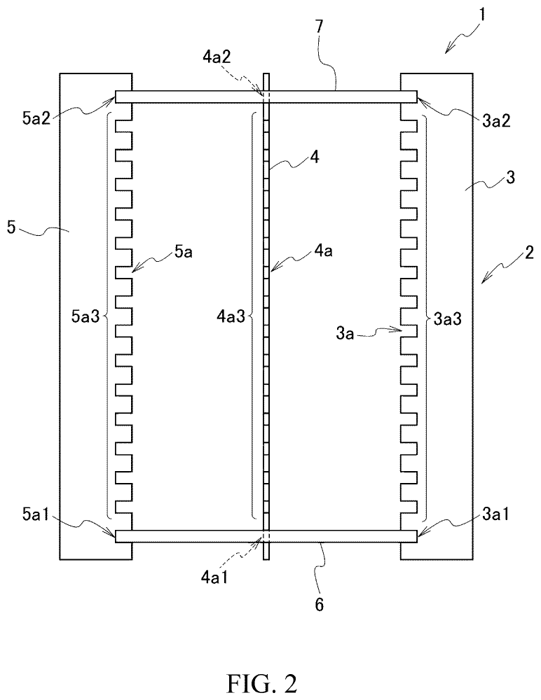

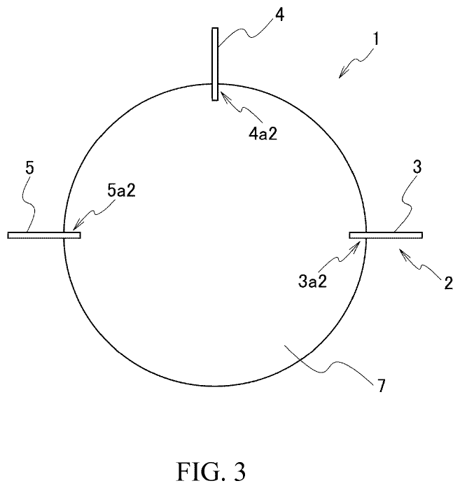

FIG. 1 shows a perspective view of a support tool 1 according to an embodiment. FIG. 2 shows a front view of the support tool 1, and FIG. 3 shows a top view of the support tool 1. The support tool 1 can accommodate and support a temporary substrate inside, and a SiC polycrystalline growth layer can be formed on a surface of a semiconductor substrate supported on a main surface of the temporary substrate by CVD. In addition, a first support plate 3, a second support plate 4, and a third support plate 5 serving as support plates of the embodiment constitute a support 2 that surround and support the temporary substrate accommodated in the support tool 1 from three sides.

The support tool 1 includes the support 2 composed of the first support plate 3, the second support plate 4, and the third support plate 5, and a first dummy substrate 6 and a second dummy substrate 7 engaged with the support 2. The support 2 is fitted with and fixed to the first dummy substrate 6 and the second dummy substrate 7 to form the support tool 1. The support tool 1 forms a space surrounded by the support 2, the first dummy substrate 6, and the second dummy substrate 7 so as to accommodate and support the temporary substrate.

The first support plate 3, the second support plate 4, and the third support plate 5 constituting the support 2 have a rectangular plate shape, and a plurality of grooves 3a, 4a, and 5a are respectively formed in a comb shape along one long side thereof. The first support plate 3, the second support plate 4 and the third support plate 5 are arranged with one long side parallel to each other, and the first dummy substrate 6 having a disk-like shape is inserted and fitted into first grooves 3a1, 4a1, 5a1, each located at one end of the long side among the plurality of grooves 3a, 4a, 5a, with its main surface oriented orthogonally to the one long side. In addition, the second dummy substrate 7 having a disk-like shape like the first dummy substrate 6 is inserted and fitted into second grooves 3a2, 4a2, 5a2, each located at the other end of the long side, with its main surface oriented orthogonally to the one long side. The first dummy substrate 6 and the second dummy substrate 7 are held parallel to each other by the first support plate 3, the second support plate 4 and the third support plate 5 arranged along their periphery. Among the plurality of grooves 3a, 4a, 5a, the third grooves 3a3, 4a3, 5a3, other than the first grooves 3a1, 4a1, 5al and the second grooves 3a2, 4a2, 5a2, receive and support the temporary substrate that also has a disk-like shape like the first dummy substrate 6 and the second dummy substrate 7 on one long side when the temporary substrate is inserted thereto with a bottom surface as its main surface and/or a bottom surface oriented orthogonally to the one long side.

The support 2 opens on the front of the support tool 1 so that the temporary substrate can be inserted from the outside of the support tool 1 and accommodated in the space surrounded by the support 2, the first dummy substrate 6 and the second dummy substrate 7. Among the first support plate 3, the second support plate 4, and the third support plate 5 that constitute the support 2, for example, a pair of support plates, such as the first support plate 3 and the third support plate 5, are arranged facing each other with the first dummy substrate 6 and the second dummy substrate 7 interposed therebetween, and the remaining second support plate 4 is arranged on the opposite side to the front side of the support tool 1 with respect to the plane including the first support plate 3 and the third support plate 5. By arranging the support 2 in this way, it is ensured that the temporary substrate having an orientation with its main surface orthogonal to one long side is inserted from the front of the support tool 1 toward the second support plate 4 through an opening between the first support plate 3 and the third support plate 5 of the support 2 and accommodated in the space surrounded by the support 2, the first dummy substrate 6 and the second dummy substrate 7.

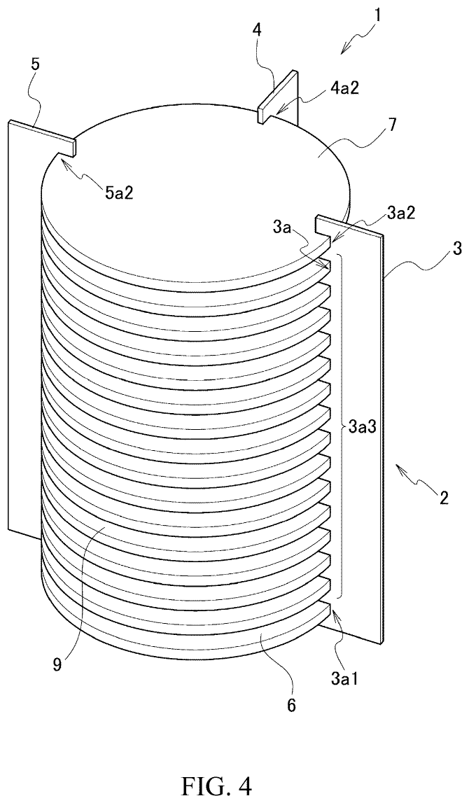

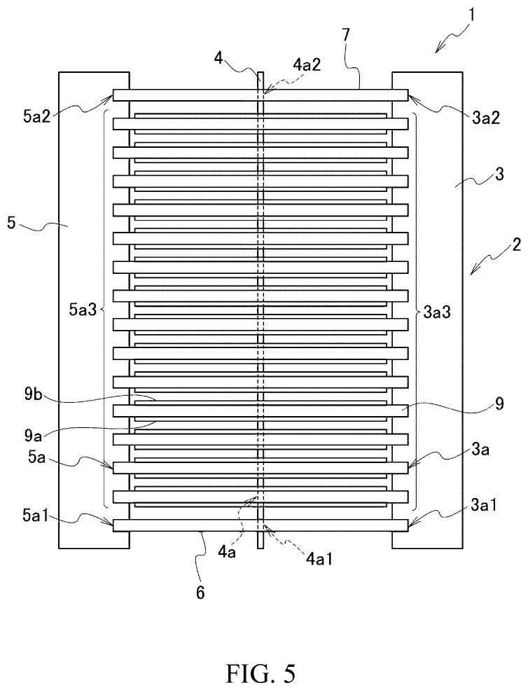

FIG. 4 shows a perspective view of the support tool 1 accommodating the temporary substrate 9. FIG. 5 shows a front view of the support tool 1 accommodating the temporary substrate 9. In the support tool 1, a plurality of temporary substrates 9 are accommodated in a space surrounded by the support 2, the first dummy substrate 6, and the second dummy substrate 7. In the space, the temporary substrate 9 is inserted into the third grooves 3a3, 4a3, 5a3 with its main surface orthogonal to one long side, and is supported in the direction of the one long side. The third grooves 3a3, 4a3, 5a3 are grooves among the plurality of grooves 3a, 4a and 5a, except the first grooves 3a1, 4a1, 5a1 and the second grooves 3a2, 4a2, 5a2 that engage respectively with the first dummy substrate 6 and the second dummy substrate 7.

The temporary substrate 9 of the embodiment has a disk-like shape having a predetermined diameter and thickness, and as shown in FIG. 5, a first semiconductor substrate 9a is supported on a bottom surface and a second semiconductor substrate 9b is supported on a top surface. The temporary substrate 9 contains graphite, and may also contain other materials such as SiC. As described below, the first semiconductor substrate 9a and the second semiconductor substrate 9b are semiconductor substrates including a laminate of SiC single crystal substrates. The first semiconductor substrate 9a and the second semiconductor substrate 9b are respectively arranged on the bottom surface and the top surface of the temporary substrate 9 in areas other than the edge portion from the outer periphery to a predetermined distance from the outer periphery. In other words, a predetermined range from the outer periphery of the bottom surface and the top surface of the temporary substrate 9 forms an edge portion where the first semiconductor substrate 9a and the second semiconductor substrate 9b are not arranged. In FIG. 5, the first semiconductor substrate 9a and the second semiconductor substrate 9b are respectively supported on the bottom surface and the top surface of the temporary substrate 9. However, the temporary substrate 9 may also support only one of the first semiconductor substrate 9a on the bottom surface and the second semiconductor substrate 9b on the top surface.

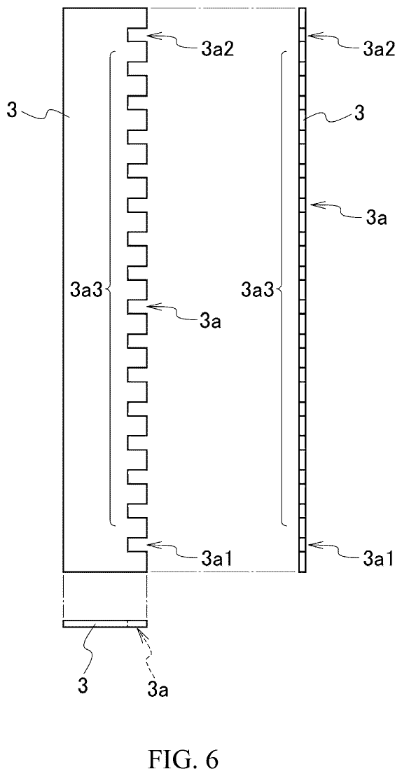

FIG. 6 shows a front view, a side view and a bottom view of the first support plate 3. The first support plate 3 is a graphite plate having a rectangular plate shape, and may have a length and width of 250 mm×25 mm and a thickness of 2 mm, for example. In the first support plate 3, a plurality of grooves 3a are formed in a comb shape at predetermined intervals along one long side. Among the plurality of grooves 3a, the third groove 3a3 other than the first groove 3a1 fitted with the first dummy substrate 6 and the second groove 3a2 fitted with the second dummy substrate 7 is formed to have the size that can support the inserted temporary substrate 9. For example, when the temporary substrate 9 has a thickness of 2 mm, the width of the third groove 3a3 can be set to 2.1 mm, and its depth can be set to ((a diameter of the temporary substrate 9)−(a diameter of the first semiconductor substrate 9a or the second semiconductor substrate 9b))/2−2 mm. The number and spacing of the third grooves 3a3 supporting the temporary substrates 9 are adjusted according to the number of temporary substrates 9 accommodated in the support tool 1, the sizes of the first semiconductor substrate 9a and the second semiconductor substrate 9b, and the like. For example, when the first semiconductor substrate 9a and the second semiconductor substrate 9b are 4-inch wafers and 25 temporary substrates 9 are accommodated in the support tool 1, the number of the third groove 3a supporting the temporary substrate 9 may be set to at least 27 and the spacing may be set to at least 8 mm.

The first groove 3a1 and the second groove 3a2 to be engaged with the first dummy substrate 6 and the second dummy substrate 7 respectively are formed to have a width and a depth that can fitted with the first dummy substrate 6 and the second dummy substrate 7 inserted in a direction with its main surface orthogonal to one long side of the first support plate 3 such that the first support plate 3 and the first dummy substrate 6 and the second dummy substrate 7 are fitted and fixed to each other without wobbling. In addition, a SiC coating may be formed on the first support plate 3 by CVD if necessary. In this case, the width of the groove 3a is set taking into consideration the thickness of the SiC coating. Here, the first support plate 3 has been described with reference to FIG. 6, but the same applies to the second support plate 4 and the third support plate 5.

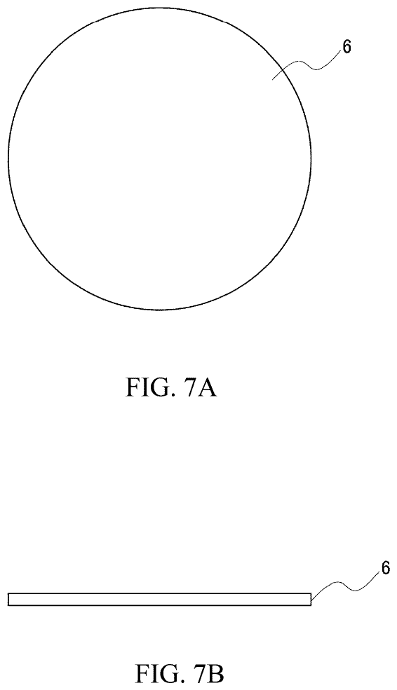

FIG. 7A shows a top view of the first dummy substrate 6. FIG. 7B shows a side view of the first dummy substrate 6. The first dummy substrate 6 is a graphite plate having a disk-like shape, and may have a thickness of 2 mm or more, for example. The first dummy substrate 6 may have the same size as the temporary substrate 9. In addition, a SiC coating may be formed on the first dummy substrate 6 by CVD as necessary. In addition, the first dummy substrate 6 is not limited to graphite, and may include other materials such as SiC. Here, the first dummy substrate 6 has been described with reference to FIG. 7, but the same applies to the second dummy substrate 7.

The support tool 1 having the above-described configuration can be assembled in the following sequence. Rectangular plate-shaped graphite plates having a specified size are prepared, and a plurality of grooves 3a, 4a, and 5a are formed in a comb-like shape along one long side at a specified spacing, width, depth, etc., thereby producing the first support plate 3, the second support plate 4 and the third support plate 5 constituting the support 2. In addition, disc-shaped graphite plates having a predetermined size are prepared to produce the first dummy substrate 6 and the second dummy substrate 7. If necessary, a SiC coating may be formed on the first support plate 3, the second support plate 4, and the third support plate 5 as well as the first dummy substrate 6 and the second dummy substrate 7 by CVD. Next, the first grooves 3a1, 4a1, 5a1 and the second grooves 3a2, 4a2, 5a2 formed in the first support plate 3, the second support plate 4 and the third support plate 5 are engaged with the peripheries of the first dummy substrate 6 and the second dummy substrate 7 respectively for assembling in this manner. In the assembled support tool 1, the first support plate 3, the second support plate 4 and the third support plate 5 are fixed so that their long sides are parallel to each other, and the first dummy substrate 6 and the second dummy substrate 7 are fixed to be parallel.

In addition, the first support plate 3, the second support plate 4 and the third support plate 5 of the embodiment have a rectangular plate shape, but they are not limited to the rectangular plate shape as long as they can constitute the support 2 of the support tool 1 and serve as columnar components with a plurality of grooves formed on an edge thereof. In addition, in the first support plate 3, the second support plate 4 and the third support plate 5, the first grooves 3a1, 4a1 and 5a1 for fitting with the first dummy substrate 6 are formed at one end of one long side among the plurality of grooves 3a, 4a, and 5a formed along the one long side of the rectangular plate-shaped first support plate 3, second support plate 4 and third support plate 5, and the second grooves 3a2, 4a2, 5a2 for fitting with the second dummy substrate 7 are formed at the other end of the one long side among the plurality of grooves 3a, 4a, and 5a, but are not limited thereto. The first grooves 3a1, 4a1, 5a1 and the second grooves 3a2, 4a2, 5a2 only need to be included in the plurality of grooves 3a, 4a, 5a, and the third grooves 3a3, 4a3, 5a3 supporting the temporary substrate 9 only need to be the remaining grooves 3a, 4a, 5a excluding the first grooves 3a1, 4a1, 5a1 fitted with the first dummy substrate 6 and the second grooves 3a2, 4a2, 5a2 fitted with the second dummy substrate 7.

The first dummy substrate 6 and the second dummy substrate 7 are configured to have a disk shape, but they may have other shapes such as a rectangular plate shape so as to have the same shape as the temporary substrate 9 accommodated in the support tool 1. In addition, the first dummy substrate 6 and the second dummy substrate 7 are not limited to one piece each, and a plurality of substrates may be overlapped to form the first dummy substrate 6 and the second dummy substrate 7 respectively.

In the temporary substrate 9, the bottom surface and the top surface as the main surfaces respectively support the first semiconductor substrate 9a and the second semiconductor substrate 9b. However, the semiconductor substrate supported by the temporary substrate 9 may be only the first semiconductor substrate 9a on the bottom surface or only the second semiconductor substrate 9b on the top surface.

As described above, the first support plate 3, the second support plate 4 and the third support plate 5 of the embodiment are composed of graphite plates, and therefore are relatively inexpensive. In addition, the support tool 1 of the embodiment includes the first support plate 3, the second support plate 4 and the third support plate 5 made of graphite plates, and the first dummy substrate 6 and the second dummy substrate 7 also made of graphite plates, so it is cheaper. Therefore, after the SiC polycrystalline growth layer is formed on the first semiconductor substrate 9a and the second semiconductor substrate 9b supported by the temporary substrate 9 through CVD in the support tool 1, the support tool 1 and the ends of the temporary substrate 9 fixed to the support tool 1 can be cut off together and discarded. In this way, the support tool 1 is cheap and can be thrown away after use, and therefore the manufacturing cost of the semiconductor substrate can also be reduced.

The support tool 1 of the embodiment can accommodate a plurality of temporary substrates 9 in a space surrounded by the support 2, the first dummy substrate 6, and the second dummy substrate 7, and the temporary substrates 9 supports the first semiconductor substrate 9a and the second semiconductor substrate 9b respectively on its bottom surface and top surface. In the support tool 1, the plurality of temporary substrates 9 are supported by the third grooves 3a3, 4a3, and 5a3 formed at specified intervals along one long side of the first support plate 3, the second support plate 4, and the third support plate 5 constituting the support 2. In addition, the plurality of temporary substrates 9 supported in the support tool 1 are open in the in-plane direction of the main surface, except for the direction blocked by the first support plate 3, the second support plate 4 and the third support plate 5 of the support 2. Therefore, a uniform atmosphere can be provided to the plurality of temporary substrates 9 accommodated in the support tool 1 during the CVD step, so that a high-quality SiC polycrystalline growth layer 16 can be formed on the first semiconductor substrate 9a and the second semiconductor substrate 9b supported respectively on the bottom surface and the top surface of the temporary substrate 9. In addition, the support tool 1 can accommodate a plurality of temporary substrates 9, and the temporary substrate 9 supports the first semiconductor substrate 9a and the second semiconductor substrate 9b on the bottom surface and the top surface respectively. Therefore, CVD processing of a plurality of semiconductor substrates can be performed in batches, and the cost of the manufacturing method of semiconductor substrates can be reduced.

Next, the support tool 1 according to a modified example of the embodiment will be described. The support tool 1 of the modified example includes expanded graphite sheets installed in the range including the third grooves 3a3, 4a3, and 5a3 supporting the temporary substrate 9 in an area where a plurality of grooves 3a, 4a, and 5a are formed in a comb shape on one long side of the first support plate 3, the second support plate 4, and the third support plate 5. This aspect is different from the support tool 1 of the embodiment, and the other configurations are the same as the support tool 1 of the embodiment.

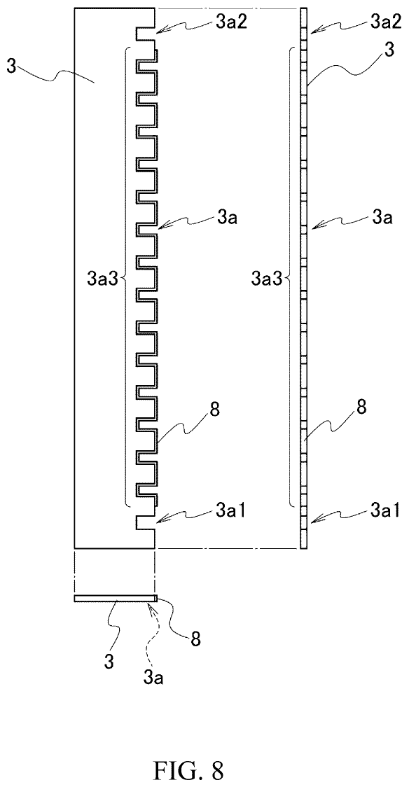

FIG. 8 shows the first support plate 3 according to the modified example. Like the first support plate of the embodiment, the first support plate 3 of the modified example is a graphite plate having a rectangular plate shape, and has a plurality of grooves 3a formed in a comb shape at predetermined intervals along one long side. In the first support plate 3 of the modified example, the expanded graphite sheet 8 is mounted in a range including the third groove 3a3 that supports the temporary substrate 9. The third groove 3a3 is a groove other than the first groove 3a1 and the second groove 3a2 fitted with the first dummy substrate 6 and the second dummy substrate 7 respectively among a plurality of grooves 3a formed along one long side. The expanded graphite sheet 8 is formed by pressing expanded graphite obtained by expanding a laminate of graphene. It is very soft and flexible, has characteristics such as excellent compressive strength, elasticity, and heat resistance, and is thus used for sealing materials requiring heat resistance, etc. In the first support plate 3 of the modified example, the expanded graphite sheet 8 is mounted in a region including the third groove 3a3 along one long side, so that the gap between the third groove 3a3 and the inserted temporary substrate 9 can be filling.

In the first support plate 3 of the modified example, since the expanded graphite sheet 8 fills the gap between the third groove 3a3 and the temporary substrate 9, when the SiC polycrystalline growth layer is formed on the surfaces of the first semiconductor substrate 9a and the second semiconductor substrate 9b supported by the temporary substrate 9 by CVD, the SiC polycrystalline growth layer can be prevented from forming between the temporary substrate 9 and the third groove 3a and causing the temporary substrate 9 to be fixed to the third groove 3a3. In addition, even if the SiC polycrystalline growth layer is formed between the temporary substrate 9 and the first support plate 3 via the graphite substrate 19 inserted into the third groove 3a3 such that the graphite substrate 19 is fixed to the first support plate 3, since the expanded graphite sheet 8 is installed in the range including the third groove 3a3 along one long side, the SiC polycrystalline growth layer is formed on the first support plate 3 with the expanded graphite sheet 8 interposed therebetween, the expanded graphite sheet 8 can be peeled off along the graphene layer so that the SiC polycrystalline growth layer can be easily detached. In this way, in the modified example, the first support plate 3 can be detached from the temporary substrate 9 after the CVD step and reused. Therefore, in the modified example, the cost of the semiconductor manufacturing method can be reduced. Here, the first support plate 3 of the modified example has been described with reference to FIG. 8, and the same applies to the second support plate 4 and the third support plate 5 of the modified example.

### Method for Manufacturing Semiconductor Substrate

Next, a method for manufacturing a semiconductor substrate using the support tool 1 of the embodiment will be described. The method for manufacturing the semiconductor substrate of the embodiment adopts a remote epitaxy method and uses the support tool 1 of the embodiment in a step of forming a SiC polycrystalline growth layer through CVD, in which a SiC epitaxial growth layer is formed with an interposed graphene layer on a surface of a SiC single crystal substrate as a seed crystal substrate so that the transfer printed SiC epitaxial growth layer can be peeled off through the graphene layer.

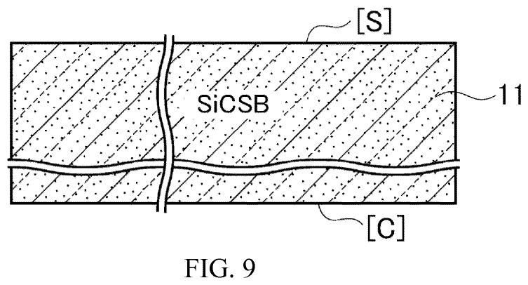

FIG. 9 is a cross-sectional view of a SiC single crystal substrate (SiCSB) 11 serving as the seed crystal. In the embodiment, the SiC single crystal substrate 11 is illustrated taking a 4H-SiC substrate as an example, and may be any one of a hexagonal crystal system (4H, 6H) or a cubic crystal system (3C). The thickness of the SiC single crystal substrate 11 may be, for example, between about 300 μm and about 600 μm. In addition, in FIG. 9, [C] represents the C surface of SiC, and [S] represents the Si surface of SiC. The same applies to the following figures.

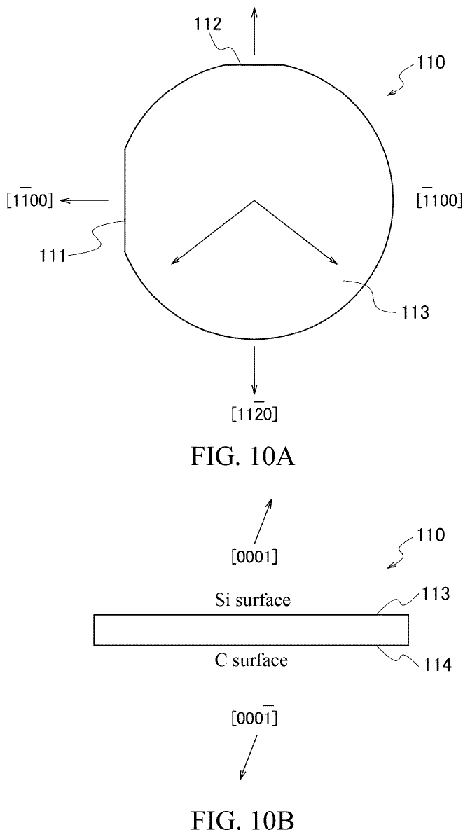

FIG. 10 is a diagram illustrating a crystal plane of a SiC wafer 110 that can be used as the SiC single crystal substrate 11. The top view of FIG. 10A shows a Si surface 113 of the SiC wafer 110 formed with a primary orientation flat 111 and a secondary orientation flat 112. In the side view of FIG. 10B viewed from the [-1100] orientation, the Si surface 113 with the orientation is formed on the upper surface, and a C surface 114 with the [000-1] orientation is formed on the lower surface.

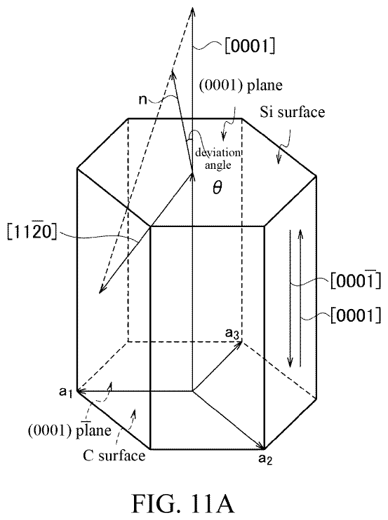

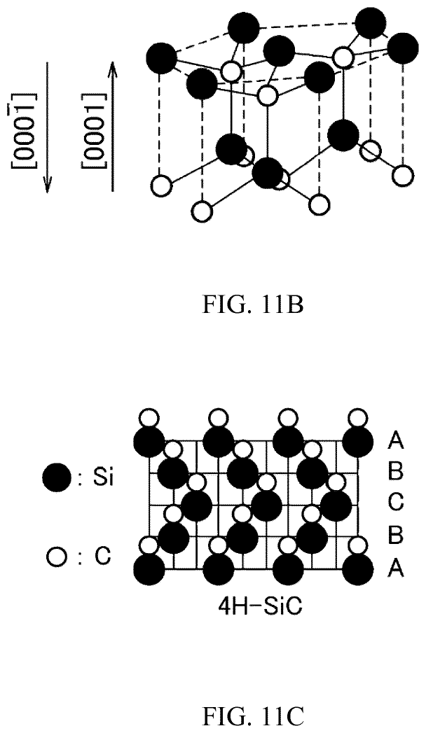

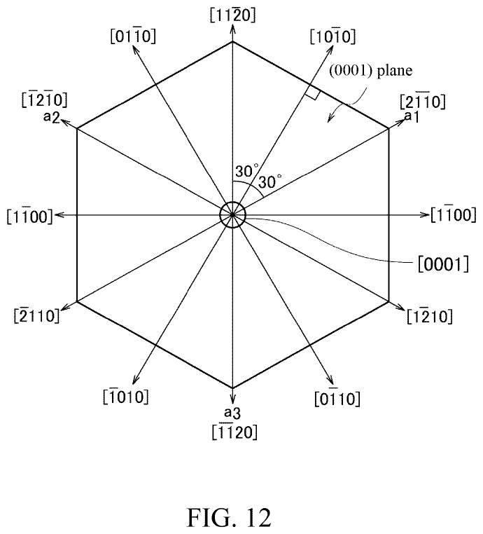

A schematic perspective view structure of a unit cell of the 4H-SiC crystal is shown in FIG. 11A. A schematic structure of a two-layer part of the 4H-SiC crystal is shown in FIG. 11B. A schematic structure of a four-layer part of the 4H-SiC crystal is shown in FIG. 11C. In addition, a schematic structure of the unit cell of the 4H-SiC crystal structure shown in FIG. 11A viewed from directly above the (0001) plane is shown in FIG. 12.

As shown in FIG. 11A to FIG. 11C, the crystal structure of 4H-SiC can be approximated by a hexagonal crystal system, with four C atoms bonded to one Si atom. The four C atoms are located at the four vertices of a regular tetrahedron with a Si atom in the center. Regarding these four C atoms, one Si atom is located in the axis direction relative to the C atom, and the other three C atoms are located on the [000-1] axis side relative to the Si atom. In FIG. 11A, the deviation angle θ is, for example, approximately 4 degrees or less.

The axis and the [000-1] axis are along the axial direction of the hexagonal prism, and the plane (the top surface of the hexagonal prism) with the axis as a normal line is the (0001) plane (Si surface). On the other hand, the plane (the lower surface of the hexagonal prism) with the [000-1] axis as the normal line is the (000-1) plane (C surface). In addition, when viewed from directly above the (0001) plane and perpendicular to the axis, the directions passing through the non-adjacent vertices of the hexagonal prism are respectively an a1 axis [2-110], an a2 axis [-12-10] and an a3 axis [-1-120].

As shown in FIG. 12, the direction passing through the vertex between the a1 axis and the a2 axis is the [11-20] axis, the direction passing through the vertex between the a2 axis and the a3 axis is the [-2110] axis, and the direction passing through the vertex between the a3 axis and the a1 axis is the [1-210] axis. Between the six axes passing through the vertices of the hexagonal prism, axes that are inclined at an angle of 30° with respect to the axes on both sides and become the normal lines of the side surfaces of the hexagonal prism are sequentially [10-10] axis, [1-100] axis, [0-110] axis, [-1010] axis, [-1100] axis and [01-10] axis in the clockwise direction from between the a1 axis and the [11-20] axis. Each surface (the side surface of the hexagonal prism) with one of these axes as the normal line is a crystal surface at right angles to the (0001) plane and the (000-1) plane.

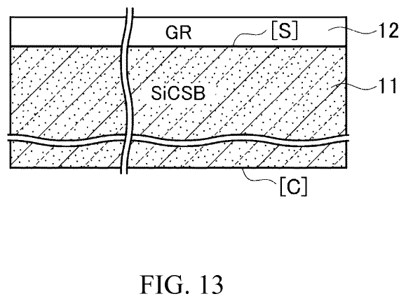

Next, as shown in FIG. 13, a graphene layer (GR) 12 within a few molecular layers is formed on the (0001) Si surface of the SiC single crystal substrate 11. The graphene layer 12 can be formed by thermal decomposition on the Si surface of the SiC single crystal substrate 11 by, for example, annealing the SiC single crystal substrate 11 in an atmospheric pressure argon atmosphere at a temperature of about 1700° C. In addition, the graphene layer 12 may be laminated and formed on the SiC single crystal substrate 11 by CVD.

The graphene layer 12 has a laminated structure of graphite sheets. The graphite sheets on each side of the laminated structure have a plurality of covalent bonds of hexagonal carbons (C), and the graphite sheets on each side are bonded by van der Waals force. The graphene layer 12 may serve as layer 0 of the buffer layer or have a single-layer structure.

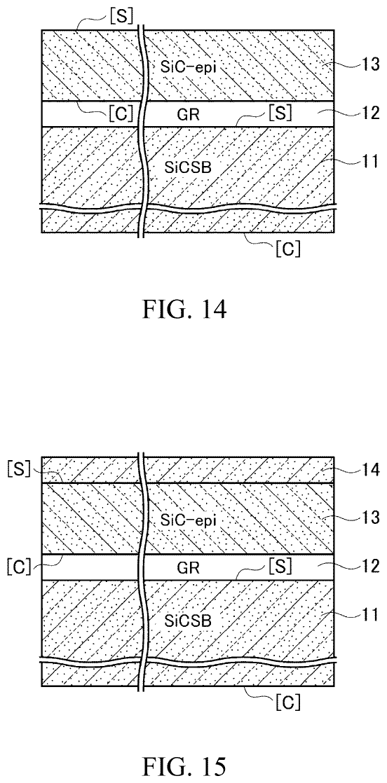

As shown in FIG. 14, a SiC epitaxial growth layer (SiC-epi) 13 is formed on the graphene layer 12. The SiC epitaxial growth layer 13 is formed on the graphene layer 12 formed on the Si surface of the SiC single crystal substrate 11 by a remote epitaxial growth method. The SiC epitaxial growth layer 13 is a single crystal SiC thin film. The surface of the SiC epitaxial growth layer 13 that is in contact with the graphene layer 12 is the C surface, and the surface of the SiC epitaxial growth layer 13 is the Si surface.

As shown in FIG. 15, a stress layer 14 is formed on the SiC epitaxial growth layer 13. The stress layer 14 is composed of a nickel (Ni) thin film. The nickel thin film can be formed by evaporation or plating. The stress layer 14 is adjusted to a size such that the internal stress can easily separate the graphene layer 12 and the SiC epitaxial growth layer 13. Therefore, the graphene layer 12 is easily peeled off the SiC epitaxial growth layer 13 due to the stress generated between the graphene layer 12 and the SiC epitaxial growth layer 13.

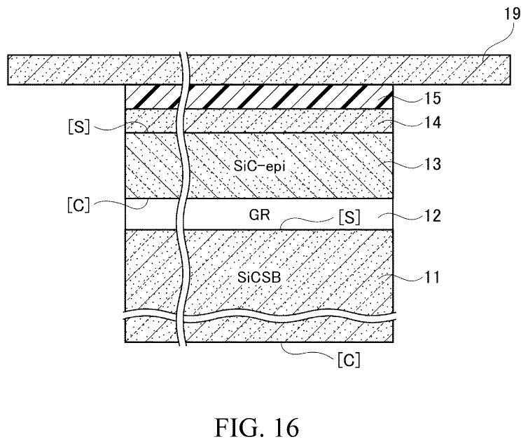

Next, as shown in FIG. 16, the adhesive layer 15 is formed on the stress layer 14, and one or both sides of a graphite substrate 19, which has an outer dimension slightly larger than that of the SiC single crystal substrate 11 and serves as a temporary substrate, is overlapped with and attached to the coated surface of the adhesive layer 15 to form a first composite body (11 (SiCSB), 12 (GR), 13 (SiC-epi), 14, 15, 19). For example, a carbon adhesive can be used for the adhesive layer 15. The carbon adhesive contains a phenol resin and is capable of maintaining bonding force even at high temperatures by carbonizing the adhesive itself. The graphite substrate 19 may be in the shape of a circular plate or a rectangular plate. As a graphite substrate 19 with a slightly larger outer dimension, the outer dimension only needs to be larger than the SiC single crystal substrate 11 by 1 mm or more. For example, if it is a SiC single crystal substrate 11 with a diameter of about 10 cm, a graphite substrate 19 with an outer dimension of about 11 cm that is about 10 mm larger in diameter can be used. For example, if the SiC single crystal substrate 11 has a diameter of about 15 cm, a graphite substrate 19 with an outer dimension of about 16 cm in diameter can be used.

Next, the first composite body is heated in an inert gas atmosphere in a thermal annealing furnace or the like to carbonize the adhesive layer 15. At this time, the adhesive layer 15 is heated gradually with a temperature gradient that can slowly desorb the gas generated when the carbon adhesive of the adhesive layer 15 decomposes, so that the adhesive surface does not peel off when the adhesive layer 15 is carbonized. The graphite substrate 19 may have a glassy carbon coating on the surface. Since the glassy carbon coating has a strong adhesive force with the carbon adhesive of the adhesive layer 15, the SiC epitaxial growth layer 13 can be easily peeled off from the graphene layer 12 and the SiC single crystal substrate 11, thereby achieving yield improvement. In addition, in FIG. 16, an example is shown in which the adhesive layer 15 is attached to one side of the graphite substrate 19 to form the first composite body. However, the adhesive layer 15 may be attached to both sides of the graphite substrate 19 to form the first composite body.

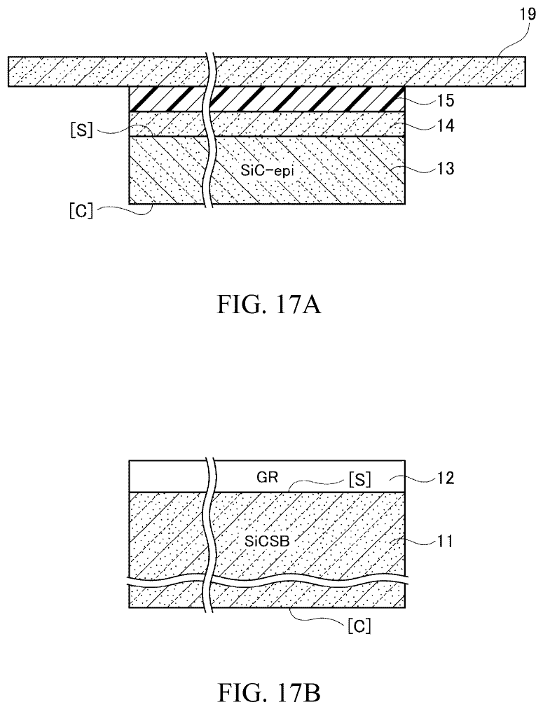

As shown in FIG. 17, after carbonizing the adhesive layer 15 of the first composite body in FIG. 16, the SiC epitaxial growth layer 13 is physically peeled off and separated from the interface with the graphene layer 12 by using an adhesive peeling tape, a peeler device, etc. on one or both sides of the first composite body. FIG. 17A is a cross-sectional view of a structure after peeling off the SiC epitaxial growth layer 13 side from the first composite body shown in FIG. 16, and FIG. 17B is a cross-sectional view of a structure after peeling off the graphene layer 12 side. The structure after peeling off the SiC epitaxial growth layer 13 side shown in FIG. 17A forms a second composite body (13 (SiC-epi), 14, 15, 19). The graphene layer 12 is adjusted to the following size: the graphene layer 12 and the SiC epitaxial growth layer 13 are bonded through the van der Waals force and easily peeled off through the stress generated by the stress layer 14; and therefore, by applying force in the shearing direction, the interface between the graphene layer 12 and the SiC epitaxial growth layer 13 is prone to peeling.

In the structure in which the graphene layer 12 side is peeled off as shown in FIG. 17B, the graphene layer 12 on the SiC single crystal substrate 11 is removed by etching or polishing. In the etching step of the graphene layer 12, for example, a plasma ashing machine using oxygen plasma may be applied. The surface of the Si surface of the SiC single crystal substrate 11 after the graphene layer 12 is etched by oxygen plasma is oxidized, so wet etching using hydrogen fluoride (HF) is performed. In addition, in the polishing step of the graphene layer 12, the graphene layer 12 is removed by, for example, chemical mechanical polishing (CMP). Here, the average roughness Ra of the Si surface of the SiC single crystal substrate 11 after the wet etching step is performed is, for example, about 1 nm or less. As a result, the SiC single crystal substrate 11 can be reused.

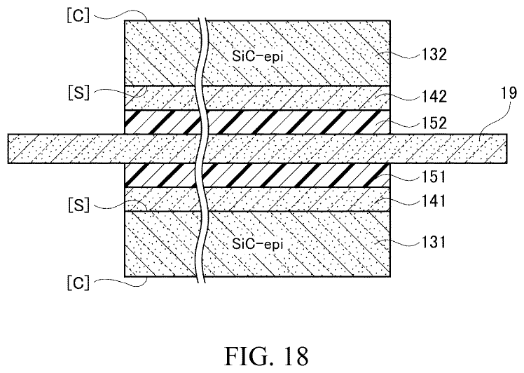

FIG. 18 shows an example in which the peeling structure of FIG. 17A is attached to both sides of the graphite substrate 19 and the SiC epitaxial growth layers 131 and 132 are disposed respectively on both sides of the graphite substrate 19. In this case, the second composite body (131 (SiC-epi), 141, 151, 19, 152, 142, 132 (SiC-epi)) is heated in a thermal annealing furnace, so that the adhesive layers 151 and 152 are carbonized.

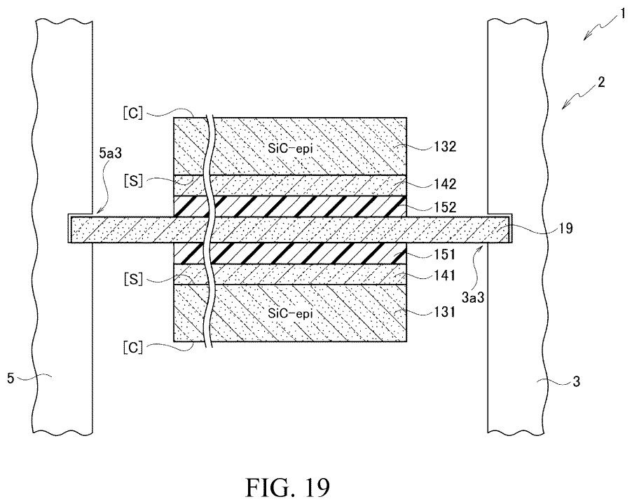

As shown in FIG. 19, the second composite body is accommodated in the support tool 1 of the embodiment. As shown in FIGS. 1 to 3, in the support tool 1, the first support plate 3, the second support plate 4 and the third support plate 5 constituting the support 2 as well as the first dummy substrate 6 and the second dummy substrate 7 forms a space capable of accommodating the second composite body including the graphite substrate 19 as the temporary substrate 9. The third grooves 3a3, 4a3 and 5a3 among the plurality of grooves 3a, 4a and 5a formed in a comb shape along one long side of each of the first support plate 3, the second support plate 4 and the third support plate 5 can support the inserted graphite substrate 19 as the second composite body in the one long side direction. As shown in FIGS. 4 and 5, the second composite body is inserted from the front of the support tool 1 and accommodated into the opening formed by the first support plate 3, the third support plate 5, the first dummy substrate 6 and the second dummy substrate 7 in an orientation in which the main surface of the graphite substrate 19 is orthogonal to one long side. The second composite body is supported in one long side direction through the graphite substrate 19 inserted into the third grooves 3a3, 4a3, and 5a3 and is ensured to have a designated interval to the adjacent second composite body, first dummy substrate 6 or second dummy substrate 7.

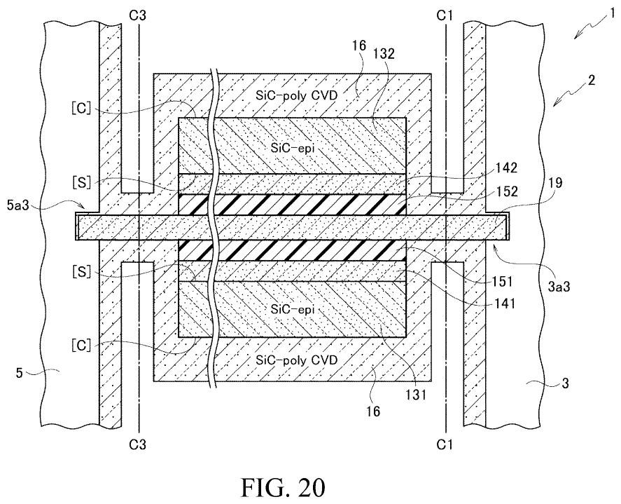

As shown in FIG. 20, a SiC polycrystalline growth layer 16 is formed on the (000-1) C plane of the SiC epitaxial growth layers 131 and 132 disposed on one or both surfaces of the second composite body. The SiC polycrystalline growth layer 16 may be formed using CVD technology. After the support tool 1 accommodating the second composite body is placed in the CVD furnace, it is evacuated and heated to about 1400° C. to 1500° C., and then, for example, SiCl₄ (silicon tetrachloride) gas, CH₄ (methane) gas and H₂ (hydrogen) gas flow in simultaneously as the material gases, and the pressure is adjusted to deposit the SiC polycrystalline growth layer 16. The SiC polycrystalline growth layer 16 has a 3C (cubic crystal) structure. The film thickness of the deposited SiC polycrystalline growth layer 16 can be set according to the thickness of the SiC composite substrate in the final form. For example, when the overall thickness of the SiC composite substrate is set to 350 μm, if, for example, the SiC epitaxial growth layer 13 has a film thickness of 10 μm, then the deposited film thickness of the SiC polycrystalline growth layer 16 only needs to be set to 340 μm.

As shown in FIG. 20, the SiC polycrystalline growth layer 16 is deposited on the second composite body to form a third composite body (16 (SiC-poly CVD), 131 (SiC-epi), 141, 151, 19, 152, 142, 132 (SiC-epi), 16 (SiC-poly CVD)). The third composite body is fixed to the support tool 1 through the SiC polycrystalline growth layer 16 extending from the graphite substrate 19 to the support tool 1 for accommodating.

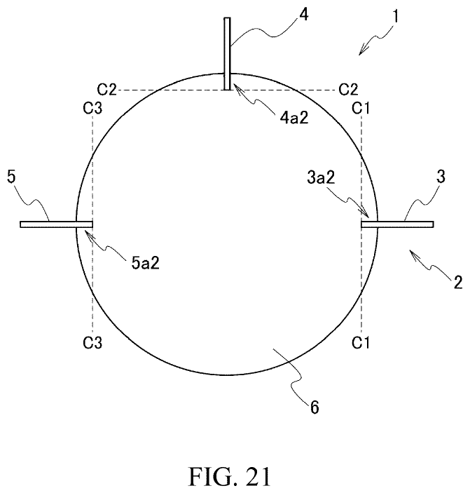

As shown in the top view of FIG. 21, along the cutting line Cl between the third composite body and the first support plate 3 and the cutting line C3 between the third composite body and the third support plate 5 shown in FIG. 20, and also along the cutting line C2 between the third composite body and the second support plate 4, the graphite substrate 19 and the SiC polycrystalline growth layer 16 are cut off, thereby cutting the third composite body from the support tool 1. When cutting the graphite substrate 19 and the SiC polycrystalline growth layer 16 along the cutting lines C1, C2, and C3, a chain saw can be used. After the third composite body is cut out, the support tool 1 to which the remaining graphite substrate 19 and the like are fixed is discarded.

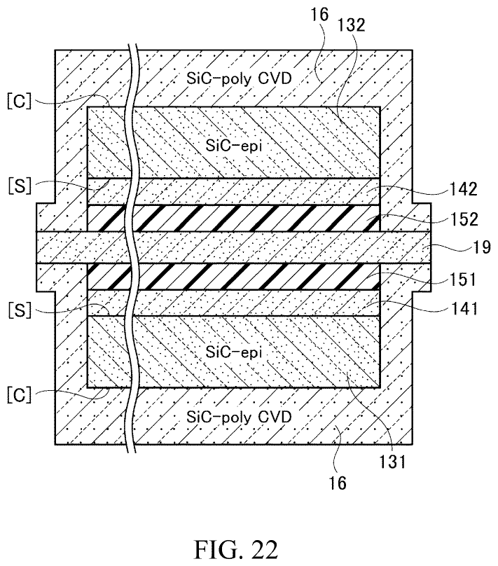

The third composite body cut out from the support tool 1 is shown in FIG. 22. The third composite body is cut out by cutting the graphite substrate 19 inserted into the third grooves 3a3, 4a3, and 5a3 of the first support plate 3, the second support plate 4, and the third support plate 5 together with the SiC polycrystalline growth layer 16 formed by extending into the support tool 1. Therefore, the cut surface of the graphite substrate 19 is exposed from the third composite body.

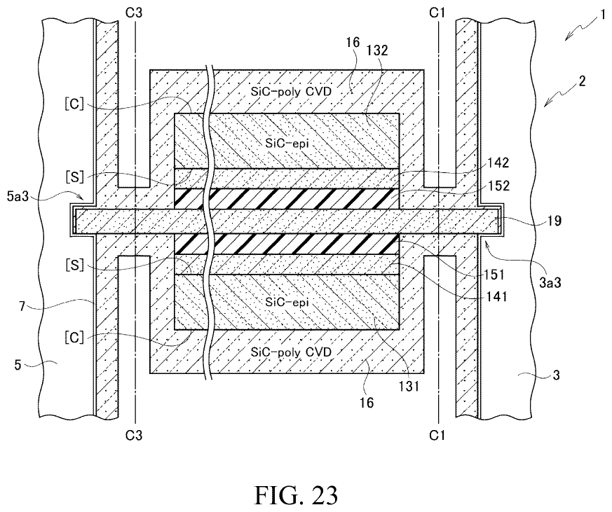

In addition, as shown in FIG. 23, the second composite body may be accommodated in the support tool 1 of the modified example. As shown in FIG. 8, in the support tool 1 of the modified example, the expanded graphite sheets 8 are installed respectively within the range of the third grooves 3a3, 4a3, and 5a3 supporting the graphite substrate 19 among the plurality of grooves 3 formed along one long side of the first support plate 3, the second support plate 4, and the third support plate 5. Also in the case of using the support tool 1 of the modified example, the third composite body (16 (SiC-poly CVD), 131 (SiC-epi), 141, 151, 19, 152, 142, 132 (SiC-epi), 16 (SiC-poly CVD)) is formed by depositing the SiC polycrystalline growth layer 16 on the second composite body.

In the support tool 1 of the modified example, the expanded graphite sheet 8 fills the gap between the graphite substrate 19 and the third grooves 3a3, 4a3, and 5a3. Therefore, when the SiC polycrystalline growth layer 16 is formed in the second composite body, the SiC polycrystalline growth layer 16 is prevented from being formed between the graphite substrate 19 and the third grooves 3a3, 4a3, and 5a3 so that the temporary substrate 9 is firmly connected to the third grooves 3a3, 4a3, and 5a3. In addition, even if the SiC polycrystalline growth layer 16 is formed between the graphite substrate 19 and the first support plate 3, the second support plate 4, and the third support plate 5 such that the graphite substrate 19 is firmly connected to the first support plate 3, the second support plate 4 and the third support plate 5, because the expanded graphite sheet 8 is mounted in the range including the third grooves 3a3, 4a3, 5a3 along a long side, the SiC polycrystalline growth layer 16 is formed on the first support plate 3, the second support plate 4 and the third support plate 5 with the expanded graphite sheet 8 interposed therebetween so that the removing is easy by peeling off the expanded graphite sheet 8 along the graphene layer. The support tool 1 of the modified example can be reused after the SiC polycrystalline growth layer 16 is removed.

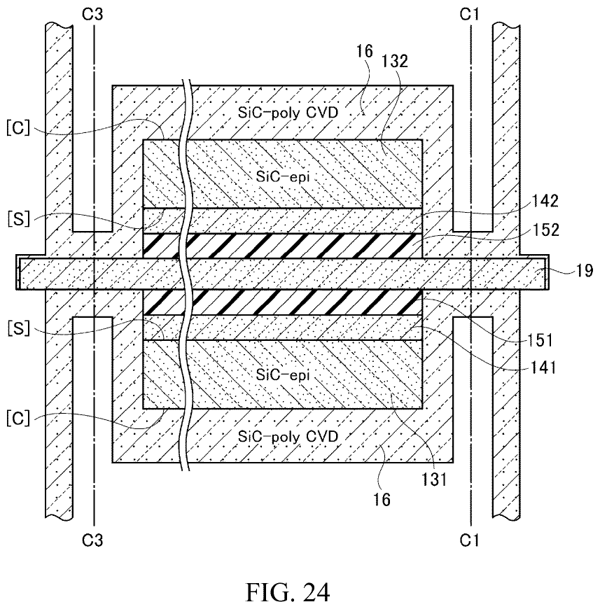

FIG. 24 is a diagram showing that the third composite body is removed from the support tool 1 of the modified example. From the support tool 1 of the modified example, not only the third composite body but also the SiC polycrystalline growth layer 16 formed into a film extending from the graphite substrate 19 to the support tool 1 is removed. Since the SiC polycrystalline growth layer 16 extending from the third composite body along the graphite substrate 19 to the support tool 1 is unnecessary, it is cut and removed using the cutting lines C1, C3, etc. in the figure, obtaining the third composite body as shown in FIG. 22.

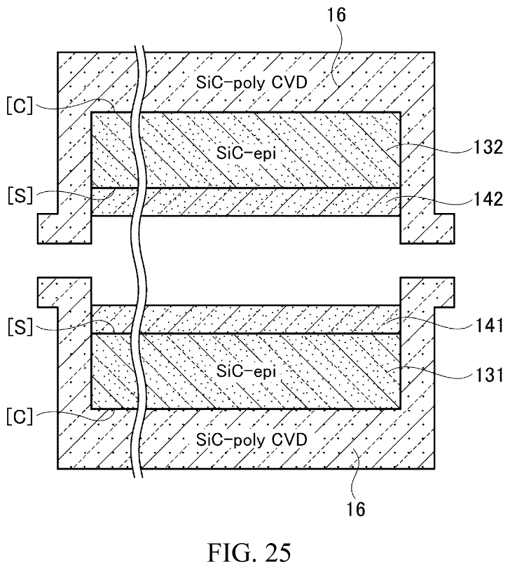

As shown in FIG. 25, in an atmospheric furnace capable of heating in an atmospheric atmosphere, the third composite body with the graphite substrate 19 exposed as shown in FIG. 22 is heated to about 900° C. to 1000° C. under atmospheric circulation, so that the graphite substrate 19 and the carbonized adhesive layers 151 and 152 inside the third composite body are burned and completely removed. Next, the fourth composite body (16 (SiC-poly CVD), 131 (SiC-epi), 141, 142, 132 (SiC-epi), 162 (SiC-poly CVD)) is taken out.

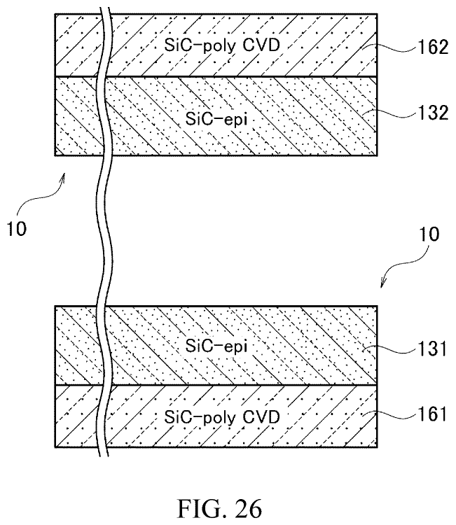

As shown in FIG. 26, the SiC polycrystalline growth layers 161 and 162 on the periphery of the fourth composite body are removed by grinding and polishing using an angle grinding device, and the stress layers 141 and 142 are removed by etching or polishing, thereby obtaining the SiC composite substrate 10 composed of the SiC polycrystalline growth layer 161 and the laminated SiC epitaxial growth layer 131, and the SiC composite substrate 10 composed of the SiC epitaxial growth layer 132 and the laminated SiC polycrystalline growth layer 162. Furthermore, these SiC composite substrates 10 are processed into required sizes and surface conditions.

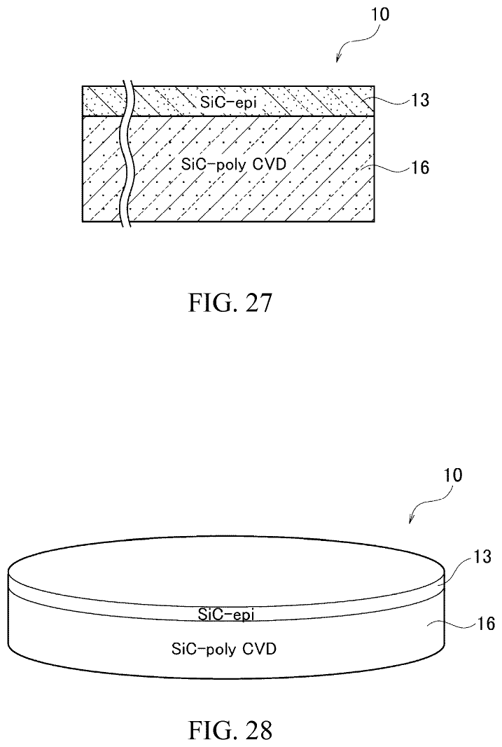

As shown in FIG. 27, the SiC composite substrate 10 is composed of the SiC polycrystalline growth layer (SiC-poly CVD) 16 and the SiC epitaxial growth layer (SiC-epi) 13 laminated thereon. FIG. 28 is a schematic perspective view of the SiC composite substrate (wafer) 10. In the SiC composite substrate 10, the surface of the SiC epitaxial

growth layer 13 may be the Si surface in the orientation of 4H-SiC, and the surface connected to the SiC polycrystalline growth layer 16 may be the C surface in the [000-1] orientation of 4H-SiC.

As described above, in the semiconductor manufacturing method of the embodiment, in the step of forming the SiC polycrystalline growth layer 16 on the SiC epitaxial growth layer 13 by CVD, the graphite substrate 19, which serves as the temporary substrate 9 for supporting the SiC epitaxial growth layer 13, is accommodated in the support tool 1 of the embodiment. The support tool 1 of the embodiment includes the first support plate 3, the second support plate 4 and the third support plate 5, all of which are made of graphite plates, as well as the first dummy substrate 6 and the second dummy substrate 7, both of which are also made of graphite plates, so it is cheaper. Therefore, after the SiC polycrystalline growth layer is formed on the first semiconductor substrate 9a and the second semiconductor substrate 9b supported by the temporary substrate 9 through CVD in the support tool 1, the support tool 1 can be cut out together with the end of the graphite substrate 19 fixed thereto and discarded. In this way, the support tool 1 can be thrown away after use because it is cheap, thereby also reducing the cost of the method for manufacturing the semiconductor substrate.

In addition, in the semiconductor manufacturing method of the embodiment, the support tool 1 of the embodiment used in the step of forming the SiC polycrystalline growth layer 16 on the SiC epitaxial growth layer 13 by CVD can accommodate a plurality of temporary substrates 9 in the space surrounded by the support 2, the first dummy substrate 6 and the second dummy substrate 7, and the plurality of temporary substrates 9 respectively support the first semiconductor substrate 9a and the second semiconductor substrate 9b on the bottom surface and the top surface thereof. In the support tool 1, the plurality of temporary substrates 9 are supported at specified interval by the third grooves 3a3, 4a3, 5a3 formed on one long side of the first support plate 3, the second support plate 4 and the third support plate 5 constituting the support 2. In addition, a plurality of graphite substrates 19 as the temporary substrates 9 supported in the support tool 1 are open in the in-plane direction of the main surface, except the orientation covered by the first support plate 3, the second support plate 4 and the third support plate 5 of the support 2. Therefore, a uniform atmosphere can be provided to the plurality of temporary substrates 9 accommodated in the support tool 1 during the CVD step, so that the SiC polycrystalline growth layer 16 with high-quality can be formed on the first semiconductor substrate 9a and the second semiconductor substrate 9b supported respectively on the bottom surface and the top surface of the temporary substrate 9. In addition, the support tool 1 can accommodate a plurality of temporary substrates 9, each of which supports the first semiconductor substrate 9a and the second semiconductor substrate 9b on its bottom and top surfaces respectively. Therefore, the CVD processing of a plurality of semiconductor substrates can be performed in batches, and the cost of the method for manufacturing semiconductor substrates can be reduced.

According to the semiconductor manufacturing method of the embodiment, before forming the SiC polycrystalline growth layer 16 using the CVD method, the SiC single crystal substrate 11 is separated and replaced with the graphite substrate 19 as a highly heat-resistant temporary substrate, thereby preventing the SiC polycrystalline from unnecessary attachment to the SiC single crystal substrate 11. As a result, the recyclability of the SiC single crystal substrate 11 can be improved and cost reduction can be achieved.

According to the semiconductor manufacturing method of the embodiment, by using the graphite substrate 19 as a high heat-resistant temporary substrate that is slightly larger in size than the SiC single crystal substrate 11, it is possible to insert and accommodate the graphite substrate 19 in the support tool 1 of the embodiment for performing epitaxial growth on one or both sides, which enables high-throughput and low-cost production without increasing growth rates.

According to the semiconductor manufacturing method of the embodiment, by carbonizing the highly heat-resistant substrate such as the graphite substrate 19 and the adhesive layer 15, the semiconductor substrate structure formed on both sides of the graphite substrate 19 can be separated economically by simply calcining it in an oxidation furnace or the like.

According to the semiconductor manufacturing method of the embodiment, the SiC is formed by remote epitaxial growth with the graphene interposed on the SiC single crystal substrate 11, and the SiC polycrystalline growth layer 16 is formed directly on the SiC using the CVD method. Therefore, there is no need for substrate bonding, and defects caused by substrate bonding can be eliminated. In addition, since the epitaxial growth layer is formed with the graphene layer 12 interposed, the SiC single crystal substrate 11 and the SiC epitaxial growth layer 13 are easily separated, making the process steps simple.

According to the semiconductor manufacturing method of the embodiment, after the SiC single crystal substrate is removed, the support tool 1 in which the graphite substrate 19 as a highly heat-resistant process substrate is inserted and accommodated is subjected to a high-temperature low pressure-chemical vapor deposition (LP-CVD) device, so that the SiC polycrystalline growth layer 16 and the like are directly grown on the SiC epitaxial growth layer 13. Therefore, there is no step of transporting the epitaxial growth layer with a film thickness of several μm from the processing substrate to the support substrate and step of bonding the epitaxial growth layer to the support substrate, thereby avoiding defects such as wrinkles, crystal transformation and voids caused by film transportation and bonding.

According to the semiconductor manufacturing method of the embodiment, the graphene layer 12 on the SiC single crystal substrate 11 is not formed by transfer printing but epitaxial growth directly thereon. In this way, defects such as wrinkles and cracks caused by the transfer printing of graphene can be avoided.

According to the semiconductor manufacturing method of the embodiment, since the SiC single crystal substrate 11 is used as the base, hexagonal crystal SiC with less decrease in crystallinity is obtained. In addition, although the SiC single crystal substrate 11 is difficult to remove by grinding or etching and is expensive, by using the remote epitaxial growth of the intervening graphene layer 12, the obtained high-performance single crystal layer can be easily separated without removing by grinding or etching. The expensive SiC single crystal substrate 11 can be reused after separation, so it can also obtain a great advantage in terms of cost.

The SiC epitaxial growth layer 13 may include at least one or more selected from the group consisting of Group IV element semiconductors, Group III-V compound semiconductors and Group II-VI compound semiconductors.

In addition, the SiC single crystal substrate 11 and the SiC epitaxial growth layer 13 may contain any one of 4H-SiC, 6H-SiC or 2H-SiC.

In addition, the SiC single crystal substrate 11 and the SiC epitaxial growth layer 13 may include at least one selected from the group consisting of GaN, BN, AlN, Al₂O₃, Ga₂O₃, diamond, carbon and graphite as a material system other than SiC.

The SiC composite substrate 10 uses a low-cost SiC polycrystalline growth layer 16 on the Si surface as the device surface instead of the high-cost SiC single crystal substrate 11.

### Modified Example of Semiconductor Manufacturing Method

Next, modified examples of the semiconductor manufacturing method of the embodiment will be described. A semiconductor manufacturing method according to the modified example uses a hydrogen ion implantation and peeling method, in which hydrogen ions are implanted into a SiC single crystal substrate to form an embrittlement layer so that the thinned layer on the surface can be peeled off. The semiconductor manufacturing method of the modified example is the same as the semiconductor manufacturing method of the embodiment except that the hydrogen ion implantation and peeling method is used in the semiconductor substrate manufacturing method.

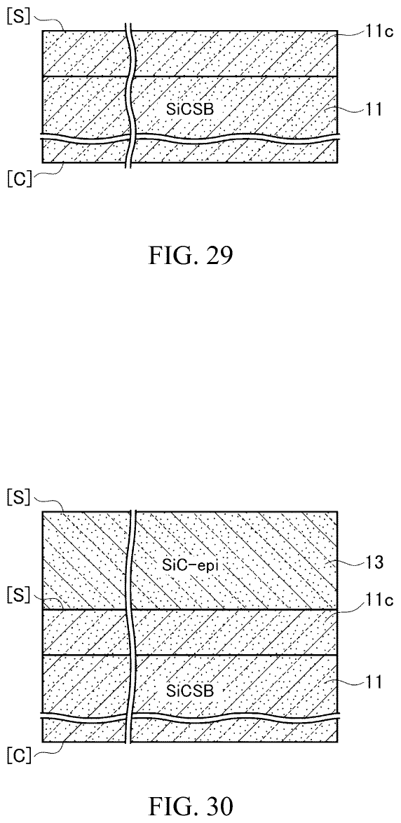

Hydrogen ions are implanted into the Si surface of the SiC single crystal substrate (SiCSB) 11 shown in FIG. 9 and an ion implantation peeling method is performed to form a hydrogen ion implantation layer 11c having a predetermined depth (for example, about 1 μm). FIG. 29 shows the SiC single crystal substrate 11 on which the hydrogen ion implantation layer 11c is formed. Here, as the ion implantation conditions, the acceleration energy can be set to about 100 keV, for example, and the dose can be set to about 2.0×10¹⁷/cm², for example. Next, the hydrogen ion implantation layer 11c is subjected to high temperature treatment to embrittle the hydrogen ion implantation layer 11c. After the hydrogen ion implantation, it is necessary to perform embrittlement thermal annealing to generate hydrogen microbubbles, thereby making the hydrogen ion implantation layer 11c break easily.

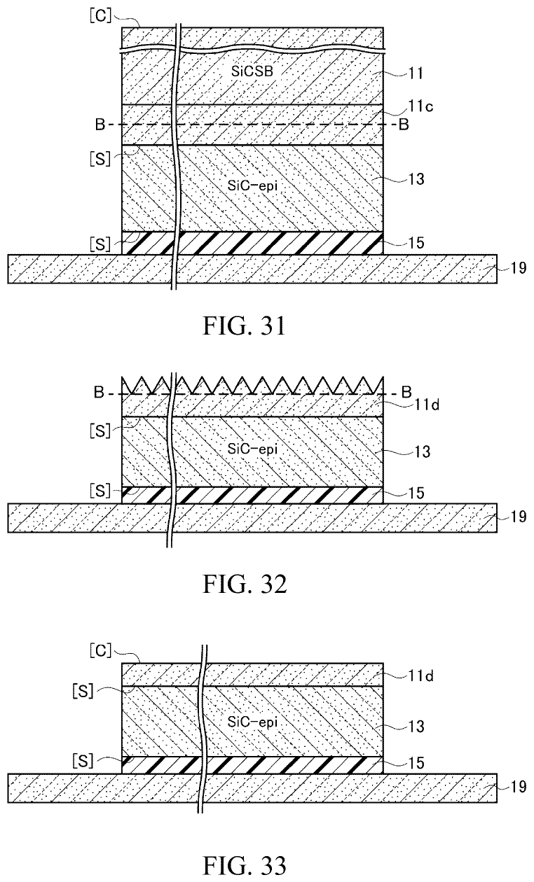

As shown in FIG. 30, the SiC epitaxial growth layer 13 is formed on the Si surface of the hydrogen ion implantation layer 11c using the CVD method. Next, as shown in FIG. 31, the Si surface of the SiC epitaxial growth layer 13 is attached to the graphite substrate 19 as a temporary substrate via the adhesive layer 15 using a carbon adhesive, and the adhesive layer 15 is carbonized by heating in a thermal annealing furnace or the like.

The embrittled hydrogen ion implantation layer 11c is divided through the peeling surface shown by line B-B in FIG. 31, and the SiC single crystal substrate 11 is thus removed. As shown in FIG. 32, a portion of the divided hydrogen ion implantation layer 11c that is in contact with the SiC epitaxial growth layer 13 becomes a thinned SiC single crystal layer 11d, which is obtained through thinning of the SiC single crystal substrate 11. On the other hand, the uneven structure formed by peeling off the Si surface of the main body of the SiC single crystal substrate 11 divided by the hydrogen ion implantation layer 11c is smoothed by mechanical polishing, mechanochemical polishing, or the like. Through the above-mentioned steps, the average roughness Ra of the Si surface of the SiC single crystal substrate 11 becomes, for example, about 1 nm or less. As a result, the SiC single crystal substrate 11 can be reused.

As shown in FIG. 33, the uneven structure on the peeling surface of the laminate of the thinned SiC single crystal layer 11d and the SiC epitaxial growth layer 13 bonded to the graphite substrate 19 is smoothed by mechanical polishing, mechanochemical polishing, or the like. The structure shown in FIG. 33 forms a fifth composite body (19, 15, 13 (SiC-epi), 11d).

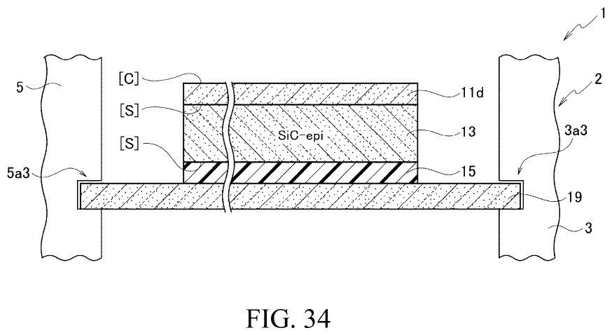

As shown in FIG. 34, the fifth composite body is accommodated in the support tool 1 of the embodiment. As shown in FIGS. 1 to 3, in the support tool 1, through the first support plate 3, the second support plate 4 and the third support plate 5 constituting the support 2 as well as the first dummy substrate 6 and the second dummy substrate 7, a space capable of accommodating the fifth composite body including the graphite substrate 19 as the temporary substrate 9 is formed. The third grooves 3a3, 4a3 and 5a3 among the plurality of grooves 3a, 4a and 5a formed in a comb shape along one long side of each of the first support plate 3, the second support plate 4 and the third support plate 5 can support the graphite substrate 19 serving as the temporary substrate 9 of the inserted fifth composite body in one long side direction. As shown in FIGS. 4 and 5, the fifth composite body is inserted from the front of the support tool 1 and accommodated in the opening formed by the first support plate 3, the third support plate 5, the first dummy substrate 6 and the second dummy substrate 7 in an orientation such that the main surface of the graphite substrate 19 is orthogonal to one long side. The fifth composite body is supported in one long side direction by the graphite substrate 19 inserted into the third grooves 3a3, 4a3, and 5a3, and is ensured to have specified spacing from the adjacent fifth composite body, first dummy substrate 6 or second dummy substrates 7.

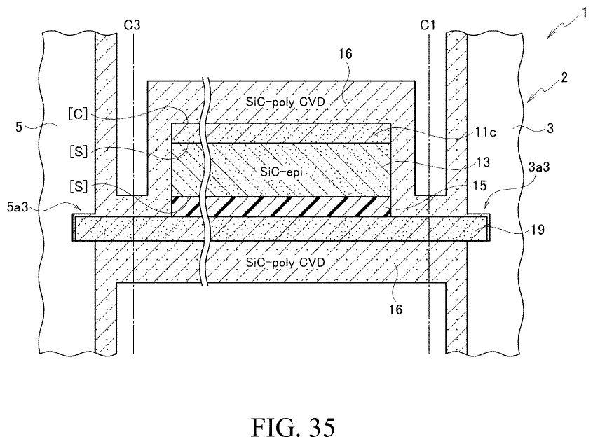

As shown in FIG. 35, the SiC polycrystalline growth layer 16 is formed on the C surface of the thinned SiC single crystal layer 11d of the fifth composite body using CVD technology, thereby forming a sixth composite body (16 (SiC-poly CVD), 19, 15, 13 (SiC-epi), 11c, 16 (SiC-poly CVD)). The sixth composite body is fixed to the support tool 1 through the SiC polycrystalline growth layer 16 extending from the graphite substrate 19 to the support tool 1 for accommodating.

The graphite substrate 19 and the SiC polycrystalline growth layer 16 are cut off along the cutting line C1 between the sixth composite body and the first support plate 3 as well as the cutting line C3 between the sixth composite body and the third support plate 5 shown in FIG. 35 to cut out the sixth composite body from the support tool 1. After the sixth composite body is cut out, the support tool 1 to which the remaining graphite substrate 19 and the like are fixed is discarded.

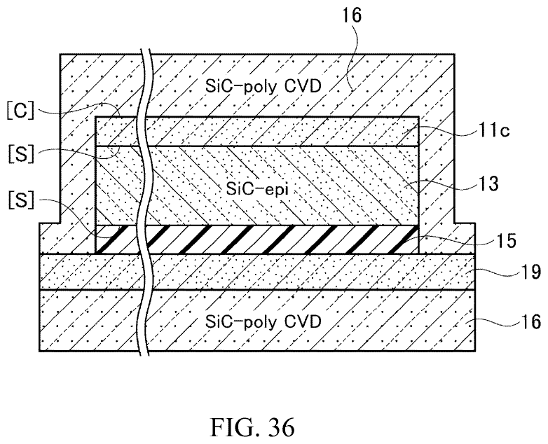

FIG. 36 shows the sixth composite body cut out from the support tool 1. The sixth composite body is cut out by cutting the graphite substrate 19 together with the SiC polycrystalline growth layer 16 formed into a film extending to the support tool 1. Therefore, the cut surface of the graphite substrate 19 is exposed from the sixth composite body.

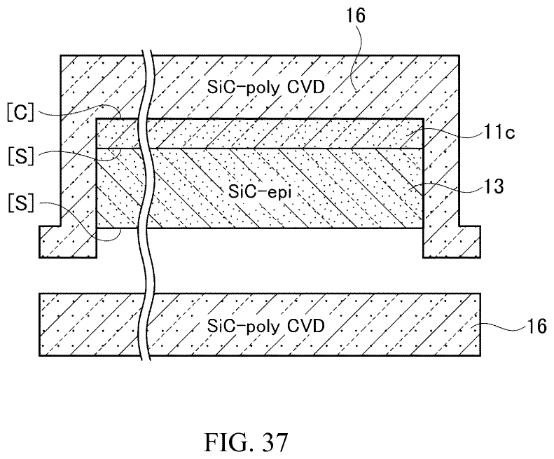

As shown in FIG. 37, the graphite substrate 19 and the carbonized adhesive layer 15 inside the sixth composite body are oxidized and burned to be removed, thereby obtaining a seventh composite body (13 (SiC-epi), 11c, 16 (SiC-poly CVD)) resulted from lamination of the SiC epitaxial growth layer 13, the thinned SiC single crystal layer 11d and the SiC polycrystalline growth layer 16 as well as the SiC polycrystalline growth layer 16 separated from the seventh composite body.

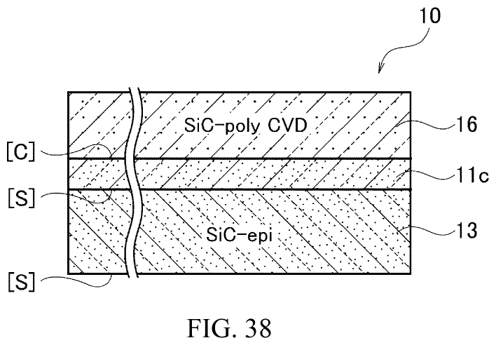

As shown in FIG. 38, the SiC polycrystalline growth layer 16 on the periphery of the seventh composite body is removed by grinding and polishing, thereby obtaining a SiC composite substrate 10. The SiC composite substrate 10 of the modified example is the same as the SiC composite substrate 10 of the embodiment except that a thinned SiC single crystal layer 11d is interposed between the SiC epitaxial growth layer 13 and the SiC polycrystalline growth layer.

In addition, as shown in FIG. 37, by oxidizing and burning the graphite substrate 19 and the adhesive layer 15, a substrate composed of a single-layer SiC polycrystalline growth layer 16 is obtained. The substrate has the same dimensions such as diameter and thickness as the SiC composite substrate 10, and thus can be used as the first dummy substrate 6 or the second dummy substrate 7 in the support tool 1.

According to the method for manufacturing a semiconductor substrate of the modified example, the SiC composite substrate 10 can also be manufactured in the same manner as the semiconductor manufacturing method of the embodiment. Therefore, the same effects as those of the semiconductor manufacturing method of the embodiment are also obtained. Furthermore, since the epitaxial growth is performed directly on the Si surface of the SiC single crystal substrate 11 without interposing a graphene layer, the SiC epitaxial growth layer 13 with a good crystal structure can be formed. In addition, according to the modified example, while the SiC composite substrate 10 is obtained, a substrate having the same size as the SiC composite substrate 10 and composed of a single-layer SiC polycrystalline growth layer can be obtained and thus used for the first dummy substrate 6 or the second dummy substrate 7.
(Note 1) A support plate 3, 4 and 5 for supporting a temporary substrate 9, wherein a SiC polycrystalline growth layer 16 can be formed on a semiconductor substrate supported on a main surface of the temporary substrate 9, the support plate 3, 4 and 5 comprising:
   a plurality of grooves 3a, 4a and 5a formed in an edge of the plurality of grooves 3a, 4a and 5a, wherein
   the plurality of grooves 3a, 4a and 5a include a groove 3a3, 4a3 and 5a3 configured to support the temporary substrate 9 inserted in a direction that the main surface is perpendicular to an extending direction of the edge. The temporary substrate 9 can be supported by the grooves 3a3, 4a3, and 5a3.
(Note 2) The support plate 3, 4 and 5 of Note 1, wherein the support plate 3, 4 and 5 is made of graphite which is inexpensive.
(Note 3) The support plate 3, 4 and 5 of Note 1, wherein the edge extends along a longitudinal direction and is formed in a comb shape by the plurality of grooves 3a, 4a and 5a. The plurality of grooves 3a, 4a, and 5a can constitute a plurality of grooves 3a3, 4a3, and 5a3 that support the temporary substrate 9.
(Note 4) The support plate 3, 4 and 5 of Note 3, wherein the support plate 3, 4 and 5 has a rectangular plate shape, and the edge is a long side of the rectangular plate shape. It is easy to manufacture because the support plate 3, 4 and 5 has a rectangular plate shape.
(Note 5) The support plate 3, 4 and 5 of Note 3 or 4, wherein an expanded graphite sheet is attached to at least a portion of the edge where the plurality of comb-shaped grooves 3a, 4a and 5a are formed. Even if the temporary substrate 9 is stuck to the support plates 3, 4 and 5 during a CVD process, it can be easily peeled off by the expanded graphite sheet.
(Note 6) A support tool 1, for the temporary substrate 9 using the support plate 3, 4 and 5 of Note 1, comprising:
   a first dummy substrate 6 and a second dummy substrate 7; and
   a support 2, supporting the first dummy substrate 6 and the second dummy substrate 7, and including at least three of the support plates 3, 4 and 5, wherein
   the support plate 3, 4 and 5 is
      fitted with the first dummy substrate 6 through a first groove 3a1, 4a1 and 5a1 of the plurality of grooves 3a, 4a and 5a, and
      fitted with the second dummy substrate 7 through a second groove 3a2, 4a2 and 5a2 of the plurality of grooves 3a, 4a and 5a,
   the support 2 is configured to support the temporary substrate 9 inserted into a third groove 3a3, 4a3 and 5a3 of the plurality of grooves 3a, 4a and 5a of the support plate 3, 4 and 5 excluding the first groove 3a1, 4a1 and 5a1 and the second groove 3a2, 4a2 and 5a2, and
   a structure of the support tool 1 can be formed by the first dummy substrate 6, the second dummy substrate 7 and the support 2 including the support plates 3, 4, and 5.
(Note 7) A support tool 1 of Note 6, wherein the first dummy substrate 6 and the second dummy substrate 7 are fixed in parallel to each other by the support 2. A space for accommodating the temporary substrate 9 can be formed by the first dummy substrate 6, the second dummy substrate 7 and the support 2.
(Note 8) The support tool 1 of Note 6, wherein the support 2 is arranged along peripheries of the first dummy substrate 6 and the second dummy substrate 7 such that the extending direction of the edge of the support plate 3, 4 and 5 are parallel to each other. By fitting the first dummy substrate 6 and the second dummy substrate 7, the structure of the support tool 1 can be formed.
(Note 9) The support tool 1 of Note 6, wherein
   the first groove 3a1, 4a1 and 5a1 is a groove at one end of the plurality of grooves 3a, 4a and 5a along the extending direction of the edge,
   the second groove 3a2, 4a2 and 5a2 is a groove at the other end along the extending direction, and
   the third grooves 3a3, 4a3 and 5a3 into which the temporary substrate 9 is inserted can be secured at the center of one edge.
(Note 10) The support tool 1 of any one of Notes 6 to 9, wherein at least one of the first dummy substrate 6 and the second dummy substrate 7 is made of graphite. It is inexpensive because it is made of graphite.
(Note 11) The support tool 1 of any one of Notes 6 to 9, wherein at least one of the first dummy substrate 6 and the second dummy substrate 7 is made of SiC. Since it is made of SiC, it is inexpensive.
(Note 12) The support tool 1 of any one of Notes 6 to 9, wherein the first dummy substrate 6 and the second dummy substrate 7 have a disk shape or a rectangular plate shape. It can be selected to correspond to the temporary substrate 9 having a disk shape or a rectangular plate shape.
(Note 13) The support tool 1 of any one of Notes 6 to 9, wherein
   a pair of support plate 3, 4 and 5s face each other with the first dummy substrate 6 and the second dummy substrate 7 interposed therebetween,
   the remaining of the support plate 3, 4 and 5s are on one side with respect to a plane including the pair of opposing support plate 3, 4 and 5s, and
   the temporary substrate 9 can be inserted from a front of the support tool 1.
(Note 14) A method for manufacturing a semiconductor substrate using the support tool 1 of Note 6, comprising:
   forming a SiC epitaxial growth layer 13 on a silicon (Si) surface of a SiC single crystal substrate 11;
   attaching the Si surface of the SiC epitaxial growth layer 13 to a graphite substrate 19;
   removing the SiC epitaxial growth layer 13 from the SiC single crystal substrate 11;
   supporting the graphite substrate 19 to which the SiC epitaxial growth layer 13 is attached using the support tool 1;
   forming a SiC polycrystalline growth layer 16 on a carbon (C) surface of the SiC epitaxial growth layer 13 attached to the graphite substrate 19;
   removing the graphite substrate 19 on which the SiC polycrystalline growth layer 16 is formed from the support tool 1; and
   removing the graphite substrate 19.

By using the support tool 1, a semiconductor substrate can be manufactured with high quality and at low cost.
(Note 15) The method of Note 14, further comprising:
   forming a graphene layer 12 on the Si surface of the SiC single crystal substrate 11, wherein
   the forming the SiC epitaxial growth layer 13 includes forming the SiC epitaxial growth layer 13 on the Si plane of the SiC single crystal substrate 11 via the graphene layer 12.

It is possible to separate the graphene layer 12 and the SiC epitaxial growth layer 13.
(Note 16) The method of Note 15, wherein the removing the SiC epitaxial growth layer 13 from the SiC single crystal substrate 11 includes peeling the SiC epitaxial growth layer 13 from the graphene layer 12. It is possible to reuse the SiC single crystal substrate 11.
(Note 17) The method of Note 15, further comprising:
   forming a stress layer 14 on the Si surface of the SiC epitaxial growth layer 13 to generate a stress that causes the SiC epitaxial growth layer 13 to separate from the graphene layer 12, wherein
   the attaching the Si surface of the SiC epitaxial growth layer 13 to the graphite substrate 19 includes attaching the Si surface of the SiC epitaxial growth layer 13 to the graphite substrate 19 via the stress layer 14.

The stress generated by the stress layer 14 makes it easy to separate the SiC epitaxial growth layer 13 and the graphene layer 12.
(Note 18) The method of Note 14, further comprising:
   forming a hydrogen ion implantation layer 11c at a predetermined depth from the Si surface of the SiC single crystal substrate 11, wherein
   the removing the SiC epitaxial growth layer 13 from the SiC single crystal substrate 11 includes embrittling the hydrogen ion implantation layer 11c to peel off the SiC epitaxial growth layer 13 together with a thinned SiC single crystal layer 11d separated by the hydrogen ion implantation layer 11c from the SiC single crystal substrate 11.

By embrittling the hydrogen ion implanted layer 11c of the SiC single crystal substrate 11, separation becomes possible.
(Note 19) The method of Note 18, further comprising polishing the C surface of the thinned SiC single crystal layer 11d that has been peeled off together with the SiC epitaxial growth layer 13. An uneven structure formed by separating the hydrogen ion implantation layer 11c can be smoothed.
(Note 20) The method of any one of Notes 14 to 19, wherein the temporary substrate 9 is made of graphite. This allows the graphite substrate 19, which is the temporary substrate 9, to be removed by combustion.
(Note 21) The method of any one of Notes 14 to 19, wherein the graphite substrate 19 has an external size greater than an external size of the SiC single crystal substrate 11. It can be inserted into the support 1 and supported.
(Note 22) The method of any one of Notes 14 to 19, wherein the graphite substrate 19 includes a glassy carbon film formed on a surface. Since the glassy carbon film has a strong adhesive force with the carbon adhesive of the adhesive layer 15, the graphene layer 12 and the SiC epitaxial growth layer 13 can be reliably separated.
(Note 23) The method of any one of Notes 14 to 19, wherein the removing the graphite substrate 19 includes burning and removing the graphite substrate 19. Since the graphite substrate 19 is a graphite substrate, it can be removed by burning in the atmosphere.
(Note 24) The method of Note 23, wherein the attaching the graphite substrate 19 to the C surface of the SiC epitaxial growth layer 13 includes attaching the SiC epitaxial growth layer 13 and the graphite substrate 19 via an adhesive layer 15 made of a carbon adhesive. Since the carbon adhesive has a strong adhesive force, the graphene layer 12 and the SiC epitaxial growth layer 13 can be reliably separated.
(Note 25) The method of Note 24, wherein the adhesive layer 15 is also burned and removed together with the graphite substrate 19 during the removing of the graphite substrate 19. The adhesive layer 15 can be removed by being burned together with the graphite substrate 19 in the air or the like.

### Other Embodiments

As mentioned above, several embodiments have been described, but the statements and drawings that form part of the disclosure are illustrative and should not be understood as limiting. Various alternative embodiments, implementations, and operational techniques will be apparent to those skilled in the art from this disclosure. In this way, the embodiments include various embodiments not described here.

### INDUSTRIAL APPLICABILITY

The present disclosure can be used in various semiconductor module technologies such as IGBT modules, diode modules, MOS modules (SiC, GaN, AIN, gallium oxide), and can also be used in power module for inverter circuit such as drives electric motors used as power sources for electric vehicles (including hybrid vehicles), trains, industrial robots, or the like. Furthermore, it can be applied to a wide range of application fields, such as power modules for inverter circuits that convert power generated by solar cells, wind power generators, and other power generation devices (particularly private power generation devices) into power from commercial power sources.

1. A support plate for supporting a temporary substrate, wherein a SiC polycrystalline growth layer can be formed on a semiconductor substrate supported on a main surface of the temporary substrate, the support plate comprising:
a plurality of grooves formed in an edge of the plurality of grooves, wherein
the plurality of grooves include a groove configured to support the temporary substrate inserted in a direction that the main surface is perpendicular to an extending direction of the edge.

2. The support plate of claim 1, wherein the support plate is made of graphite.

3. The support plate of claim 1, wherein the edge extends along a longitudinal direction and is formed in a comb shape by the plurality of grooves.

4. The support plate of claim 3, wherein the support plate has a rectangular plate shape, and the edge is a long side of the rectangular plate shape.

5. The support plate of claim 3, wherein an expanded graphite sheet is attached to at least a portion of the edge where the plurality of comb-shaped grooves are formed.

6. A support tool, for the temporary substrate using the support plate of claim 1, comprising:
a first dummy substrate and a second dummy substrate; and
a support, supporting the first dummy substrate and the second dummy substrate, and including at least three of the support plates, wherein
the support plate is
fitted with the first dummy substrate through a first groove of the plurality of grooves, and
fitted with the second dummy substrate through a second groove of the plurality of grooves, and
the support is configured to support the temporary substrate inserted into a third groove of the plurality of grooves of the support plate excluding the first groove and the second groove.

7. A support tool of claim 6, wherein the first dummy substrate and the second dummy substrate are fixed in parallel to each other by the support.

8. The support tool of claim 6, wherein the support is arranged along peripheries of the first dummy substrate and the second dummy substrate such that the extending direction of theedge of the support plate are parallel to each other.

9. The support tool of claim 6, wherein
the first groove is a groove at one end of the plurality of grooves along the extending direction of the edge, and
the second groove is a groove at the other end along the extending direction.

10. The support tool of claim 6, wherein at least one of the first dummy substrate and the second dummy substrate is made of graphite.

11. The support tool of claim 6, wherein at least one of the first dummy substrate and the second dummy substrate is made of SiC.

12. The s support tool of claim 6, wherein the first dummy substrate and the second dummy substrate have a disk shape or a rectangular plate shape.

13. The support tool of claim 6, wherein
a pair of support plates face each other with the first dummy substrate and the second dummy substrate interposed therebetween, and
the remaining of the support plates are on one side with respect to a plane including the pair of opposing support plates.

14. A method for manufacturing a semiconductor substrate using the support tool of claim 6, comprising:
forming a SiC epitaxial growth layer on a silicon (Si) surface of a SiC single crystal substrate;
attaching the Si surface of the SiC epitaxial growth layer to the temporary substrate;
removing the SiC epitaxial growth layer from the SiC single crystal substrate;
supporting the temporary substrate to which the SiC epitaxial growth layer is attached using the support tool;
forming a SiC polycrystalline growth layer on a carbon (C) surface of the SiC epitaxial growth layer attached to the temporary substrate;
removing the temporary substrate on which the SiC polycrystalline growth layer is formed from the support tool; and
removing the temporary substrate.

15. The method of claim 14, further comprising:
forming a graphene layer on the Si surface of the SiC single crystal substrate, wherein the forming the SiC epitaxial growth layer includes forming the SiC epitaxial growth layer on the Si plane of the SiC single crystal substrate via the graphene layer.

16. The method of claim 15, wherein the removing the SiC epitaxial growth layer from the SiC single crystal substrate includes peeling the SiC epitaxial growth layer from the graphene layer.

17. The method of claim 15, further comprising:
forming a stress layer on the Si surface of the SiC epitaxial growth layer to generate a stress that causes the SiC epitaxial growth layer to separate from the graphene layer, wherein
the attaching the Si surface of the SiC epitaxial growth layer to the temporary substrate includes attaching the Si surface of the SiC epitaxial growth layer to the temporary substrate via the stress layer.

18. The method of claim 14, further comprising:
forming a hydrogen ion implantation layer at a predetermined depth from the Si surface of the SiC single crystal substrate, wherein
the removing the SiC epitaxial growth layer from the SiC single crystal substrate includes embrittling the hydrogen ion implantation layer to peel off the SiC epitaxial growth layer together with a thinned SiC single crystal layer separated by the hydrogen ion implantation layer from the SiC single crystal substrate.

19. The method of claim 18, further comprising polishing the C surface of the thinned SiC single crystal layer that has been peeled off together with the SiC epitaxial growth layer.

20. The method of claim 14, wherein the temporary substrate is made of graphite.

21. The method of claim 14, wherein the temporary substrate has an external size greater than an external size of the SiC single crystal substrate.

22. The method of claim 14, wherein the temporary substrate includes a glassy carbon film formed on a surface.

23. The method of claim 14, wherein the removing the temporary substrate includes burning and removing the temporary substrate.

24. The method of claim 23, wherein the attaching the temporary substrate to the C surface of the SiC epitaxial growth layer includes attaching the SiC epitaxial growth layer and the temporary substrate via an adhesive layer made of carbon adhesive.

25. The method of claim 24, wherein the adhesive layer is also burned and removed together with the temporary substrate during the removing of the temporary substrate.
